(19) United States
(12) Patent Application Publication
(10) Pub. No.: US 2018/0334838 A1
(43) Pub. Date: Nov. 22, 2018

(54) LATCH AND ASSEMBLY USING THE SAME

(71) Applicant: GIGA-BYTE TECHNOLOGY CO.,LTD., New Taipei City (TW)

(72) Inventors: Shih-Ho CHANG, New Taipei City (TW); Yung-Shun KAO, New Taipei City (TW)

(73) Assignee: GIGA-BYTE TECHNOLOGY CO.,LTD., New Taipei City (TW)

(21) Appl. No.: 15/636,621

(22) Filed: Jun. 28, 2017

(30) Foreign Application Priority Data
May 22, 2017 (TW) 106116888

(51) Int. Cl. E05C 1/16; E05C 1/00; H05K 7/14; H01L 23/40

(52) U.S. Cl. CPC E05C 1/16; E05C 1/006; E05B 63/121; H01L 23/4093; H05K 7/1431

(57) ABSTRACT

An assembly includes a second member and a latch. The second member has a through hole. The latch includes a hollow pillar and a bolt. The hollow pillar includes a first engaging portion and a second engaging portion opposite to each other. The hollow pillar has an inserting hole. The inserting hole passes through the first engaging portion and the second engaging portion. The first engaging portion is disposed through the through hole. The bolt is inserted into the inserting hole and is movable between a first inserting position and a second inserting position. When the bolt is moved to the second inserting position along a direction from the first engaging portion pointing to the second engaging portion, the second engaging portion is expanded by the bolt to make the size of the second engaging portion become larger.

### CROSS-REFERENCE TO RELATED APPLICATIONS

This non-provisional application claims priority under 35 U. S. C. § 119(a) on Patent Application No(s). 106116888 filed in Taiwan on May 22, 2017, the entire contents of which are hereby incorporated by reference.

### TECHNICAL FIELD

The disclosure relates to a latch and an assembly using the same, more particularly to a bidirectional latch and an assembly using the same.

### BACKGROUND

The more efficient the processing unit of the electronic device is, more heat is produced, and therefore the demand of heat dissipation increases. Hence, a heat dissipating device is provided to remove the heat. Generally, the heat dissipating device is disposed on the processing unit through screws and elastic members, such as springs, to secure the heat dissipating device to an electronic board having the processing unit.

### SUMMARY

One embodiment of the disclosure provides a latch comprising a hollow pillar and a bolt. The hollow includes a first engaging portion and a second engaging portion opposite to each other. The hollow pillar has an inserting hole. The inserting hole passes through the first engaging portion and the second engaging portion. The bolt is inserted into the inserting hole and is movable between a first inserting position and a second inserting position. When the bolt is moved from the first inserting position to the second inserting position along a direction from the first engaging portion pointing to the second engaging portion, and the second engaging portion is expanded by the bolt. Therefore, the outer edge of the second engaging portion is smaller when the second engaging portion is located at the first inserting position than is located at the second inserting position.

One embodiment of the disclosure provides an assembly comprising a first object and a second object. The second object has a through hole. The latch includes a hollow pillar and a bolt. The hollow pillar includes a first engaging portion and a second engaging portion opposite to each other. The hollow pillar has an inserting hole. The inserting hole passes through the first engaging portion and the second engaging portion. The first engaging portion is disposed through the through hole. The bolt is inserted into the inserting hole and is movable between a first inserting position and a second inserting position. When the bolt is moved from the first inserting position to the second inserting position, the second engaging portion is expanded by the bolt to make the size of the second engaging portion become larger.

### BRIEF DESCRIPTION OF THE DRAWINGS

The present disclosure will become more fully understood from the detailed description given here in below and the accompanying drawings which are given by way of illustration only and thus are not intending to limit the present disclosure and wherein:

FIG. 1 is a perspective view of an assembly disposed on a first object in accordance with one embodiment of the disclosure;

FIG. 2 is a perspective view of the assembly in FIG. 1;

FIG. 3 is an exploded view of the assembly in FIG. 2;

FIG. 4 is an exploded side view of the assembly in FIG. 2;

FIGS. 5-6 are side views of an assembling process of the assembly in FIG. 2;

FIGS. 7-8 are side views of a process of assembling the assembly to the first object in FIG. 6;

FIG. 9 is a side view of an assembly in accordance with another embodiment of the disclosure; and

FIG. 10 is a perspective view of the assembly in FIG. 9 being disposed on the first object.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

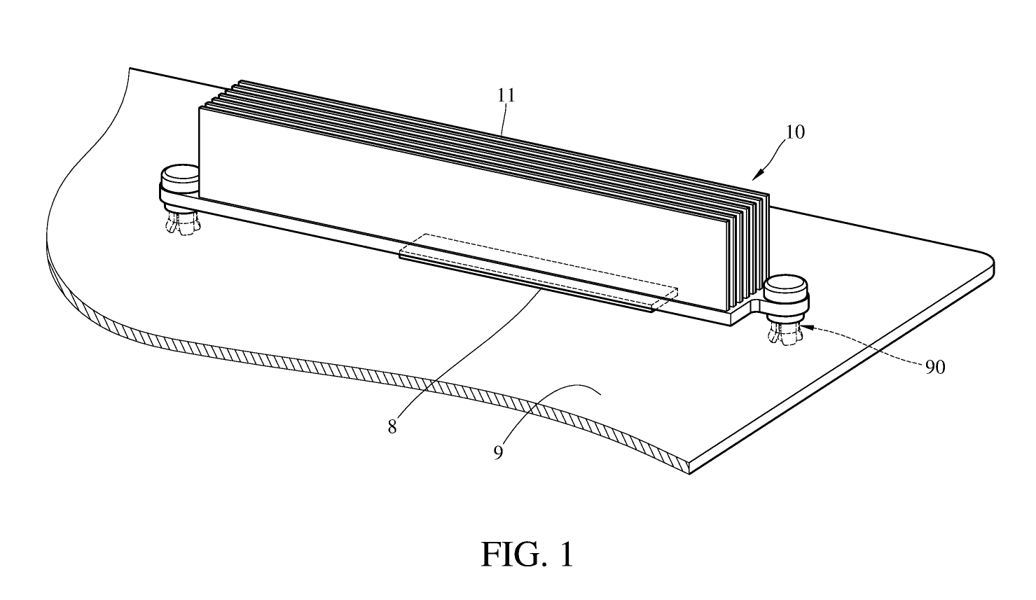

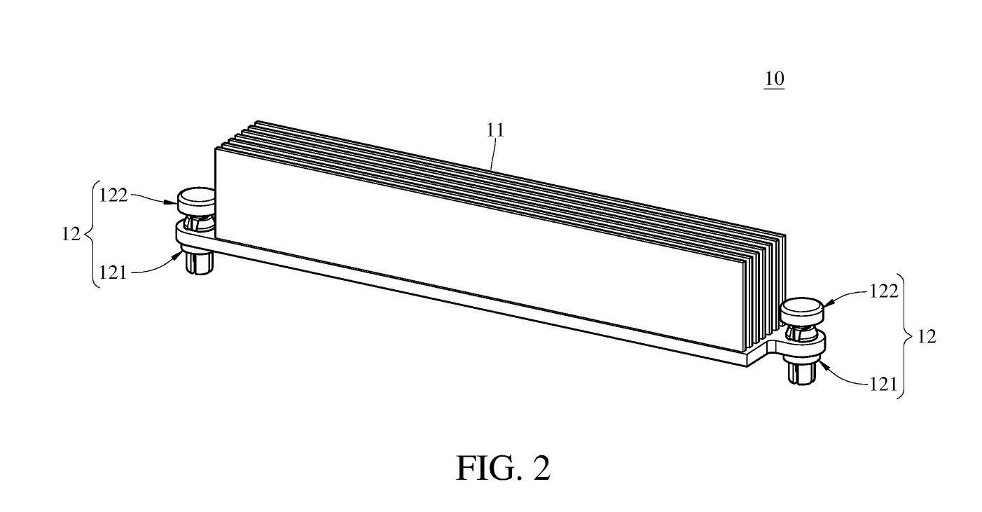

Please refer to FIG. 1 and FIG. 2. FIG. 1 is a perspective view of an assembly disposed on a first object in accordance with one embodiment of the disclosure. FIG. 2 is a perspective view of the assembly in FIG. 1. In this embodiment, the assembly 10 is able to be disposed on a first object 9 having a first through hole 90. The assembly 10 includes a second object 11 and a latch 12. A clamped member 8 can be disposed between the second object 11 and the first object 9. The latch 12 includes a hollow pillar 121 and a bolt 122. The second object 11 is able to be fixed to the first object 9 by applying the hollow pillar 121 of the latch 12 and the bolt 122. In this embodiment, the first object 9 is, for example, a circuit board, and the second object 11, is for example, a heat dissipating component. The clamped member 8 is, for example, a processing unit. However, the present disclosure is not limited thereto. In some embodiments, the first object 9 may be a dissipating component, the second object 11 may be a circuit board, and the clamped member 8 may be a chip, a heat conductive member, a heat conductive adhesive or an assembly thereof.

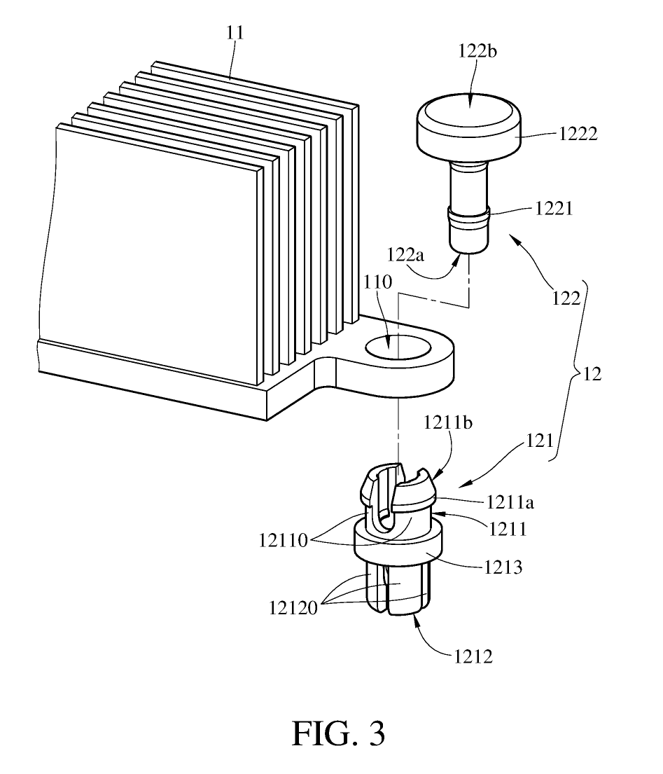

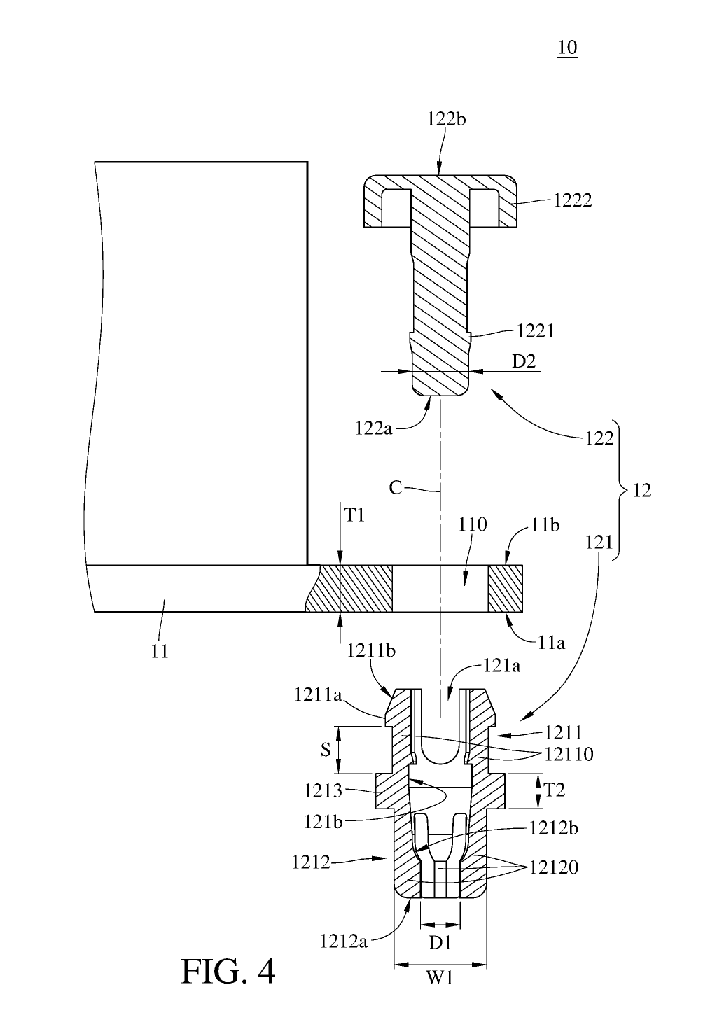

Please refer to FIG. 3 and FIG. 4. FIG. 3 is an exploded view of the assembly in FIG. 2. FIG. 4 is an exploded side view of the assembly in FIG. 2. The second object 11 has a second through hole 110.

The hollow pillar 121 of the latch 12 includes a first engaging portion 1211, a second engaging portion 1212, and a bearing block 1213. The first engaging portion 1211 and the second engaging portion 1212 are respectively located at two opposite sides of the bearing block 1213. The hollow pillar 121 has an inserting hole 121a, and the inserting hole 121a passes through the first engaging portion 1211, the second engaging portion 1212 and the bearing block 1213. The hollow pillar 121 has a positioning recess 121b at a side close to the inserting hole 121a.

The first engaging portion 1211 includes two engaging members 12110 spaced apart from each other. The engaging members 12110 surround the central axis C of the inserting hole 121a. Each engaging member 12110 has an engaging block 1211a at a side away from the inserting hole 121a. Each engaging block 1211a has a first guiding surface 1211b at a side away from the inserting hole 121a. The first guiding surface 1211b inclines toward the central axis C of the inserting hole 121a along a direction from the second engaging portion 1212 pointing to the first engaging portion 1211. Thus, when the first engaging portion 1211 is being inserted into the second through hole 110 along a direction from the bottom surface 11a of the second object 11 to the top surface 11b of the second object 11, the second object 11 is able to push the engaging block 1211a along the first guiding surface 1211b in order to move the engaging members 12110 to come closer to each other, and so that the engaging member 12110 is able to pass through the second through hole 110. When the engaging block 1211a passes through the second through hole 110, the engaging member 12110 recover to its original shape so as to be fixed to the second object 11.

In this embodiment, although the first engaging portion 1211 includes two engaging members 12110, the present disclosure is not limited thereto. In other embodiments, the first engaging portion 1211 may have more than two engaging members 12110.

The second engaging portion 1212 includes four flexible arms 12120 spaced apart from one another. The flexible arms 12120 surround the central axis C of the inserting hole 121a. Each flexible arm 12120 has a pushing block 1212a at a side close to the inserting hole 121a. Each pushing block 1212a has a second guiding surface 1212b at a side close to the inserting hole 121a. The second guiding surface 1212b inclines toward the central axis C of the inserting hole 121a along a direction from the first engaging portion 1211 pointing to the second engaging portion 1212. The pushing blocks 1212a surround an area having an inner diameter D1. In this embodiment, the number of the flexible arms 12120 is four, but the present disclosure is not limited thereto. In other embodiments, the number of the flexible arms 12120 may be adjusted.

There is a distance S between the bearing block 1213 and the engaging block 1211a, the distance S is determined by the thickness T1 of the second object 11, which is the distance between the bottom surface 11a and the top surface 11b of the second object 11. The thickness of the bearing block 1213 is determined by the thickness T3, which is the distance between the bottom surface 11a of the second object 11 and the first object 9.

The bolt 122 has a first end 122a and a second end 122b opposite to each other. When the bolt 122 is inserted into the inserting hole 121a of the hollow pillar 121 along a direction form the first engaging portion 1211 of the hollow pillar 121 pointing to the second engaging portion 1212 of the hollow pillar 121, the first end 122a of the bolt 122 is movable in the inserting hole 121a, and the second end 122b is movable outside the inserting hole 121a. The bolt 122 has a positioning protrusion 1221 between the first end 122a and the second end 122b. The first end 122a of the bolt 122 has an outer diameter D2, and the outer diameter D2 is larger than the inner diameter D1 of the pushing blocks 1212a. In this embodiment, the bolt 122 has one positioning protrusion 1221, but the present disclosure is not limited thereto. In other embodiments, the bolt 122 may have more than one positioning protrusions 1221.

Furthermore, in this embodiment, the second end 122b of the bolt 122 has a head portion 1222.

The bolt 122 is movable respect to the hollow pillar 121 so as to be moved between a first inserting position and a second inserting position. When the bolt 122 is at the first inserting position, the positioning protrusion 1221 of the bolt 122 is able to be located in positioning recess 121b of the hollow pillar 121. When the bolt 122 is moved from the first inserting position to the second inserting position along the direction from the first engaging portion 1211 pointing to the second engaging portion 1212, the positioning protrusion 1221 is able to be removed from the positioning recess 121b, and the first end 122a of the bolt 122 is able to force the flexible arms 1211a of the second engaging portions 1212 to deform and move outward along the second guiding surface 1212b of pushing block 1212a. In other words, when the bolt 122 is at the first inserting position, the second engaging portion 1212 has a first outer diameter W1 when the bolt 122 is at the first inserting portion, and has a second outer diameter W2 which is greater than the first outer diameter W1 when the bolt 122 is at the second inserting position. That is, the size of the second engaging portion 1212 becomes larger when the bolt 122 is moved from the first inserting position to the second inserting position.

Furthermore, when the bolt 122 is at the second inserting position, the head portion 1222 of the bolt 122 covers at least part of the first engaging portion 1211 of the hollow pillar 121 to make the appearance simple.

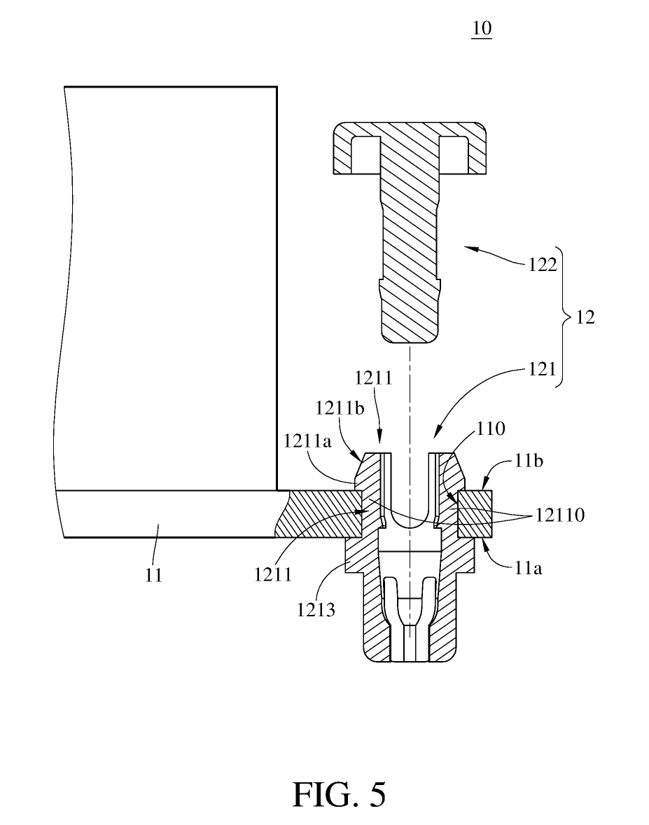

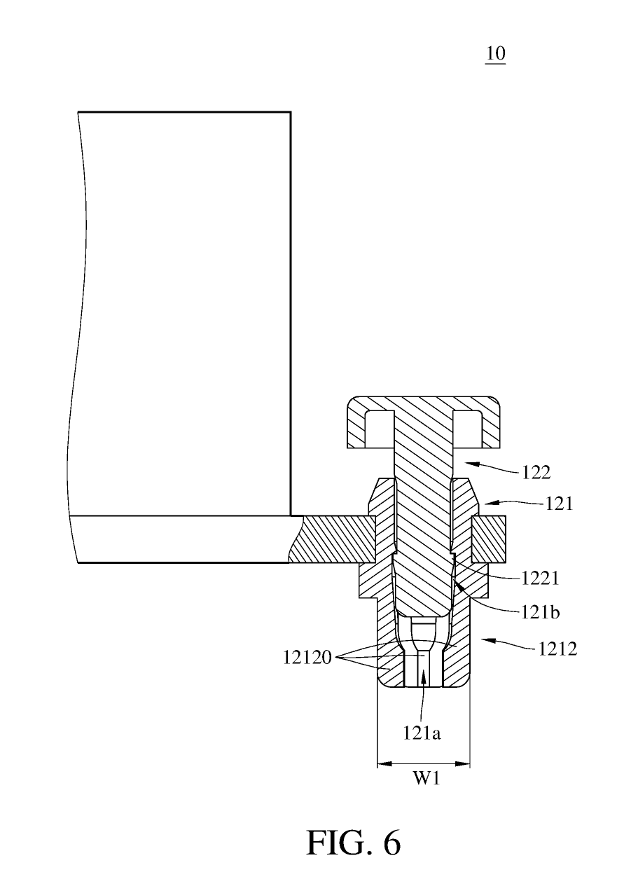

Please refer to FIG. 5 and FIG. 6. FIGS. 5-6 are side views of an assembling process of the assembly in FIG. 2. As shown in FIG. 5, firstly, the first engaging portion 1211 of the hollow pillar 121 is fixed to the second through hole 110 of the second object 11 to dispose the latch 12 to the second object 11. In detail, the engaging member 12110 of the first engaging portion 1211 is inserted into the second through hole 110 from the bottom surface 11a of the second object 11 to the top surface 11b of the second object 11. While the first engaging portion 1211 is being inserted into the second through hole 110, the second object 11 pushes the engaging block 1211a of the engaging member 12110 inward along the first guiding surface 1211b to make the engaging members 12110 to come closer to each other, so that the engaging block 1211a is able to pass through the second through hole 110. When the bearing block 1213 is in contact with the bottom surface 11a of the second object 11, the engaging members 12110 recover to its original shape so that the engaging blocks 1211a is fixed to the second object 11. When the engaging blocks 1211a is fixed to the second object 11, the second object 11 and the first engaging portion 1211 are located at the same side of the bearing block 1213, and the second object 11 is located between the engaging block 1211a and the bearing block 1213. Thus, the second object 11 and the hollow pillar 121 are firmly fixed in place.

Then, as shown in FIG. 6, the bolt 122 is inserted into the inserting hole 121a of the hollow pillar 121 to move to the first inserting position. When the bolt 122 is at the first inserting position, the positioning protrusion 1221 of the bolt 122 is located in the positioning recess 121b of the hollow pillar 121, and the assembling process of the assembly 10 is completed. Since the positioning protrusion 1221 is located in the positioning recess 121b, the bolt 122 is prevented from falling apart from the hollow pillar 121. Furthermore, before the assembly 10 is assembled to the first object 9, the bolt 122 is fixed in place at the first inserting position because the positioning protrusion 1221 is located in the positioning recess 121b. Because the flexible arms 1211a of the second engaging portion 1212 are not deformed and moved outward at this moment, the first outer diameter W1 of the second engaging portion 1212 is relatively small for the second engaging portion 1212 to be disposed on the first object 9 easily.

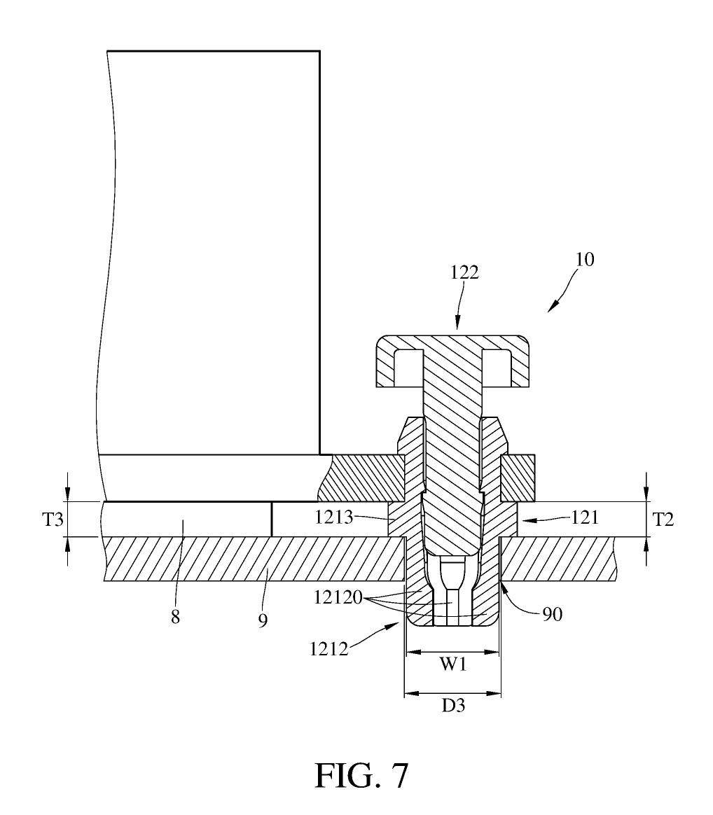

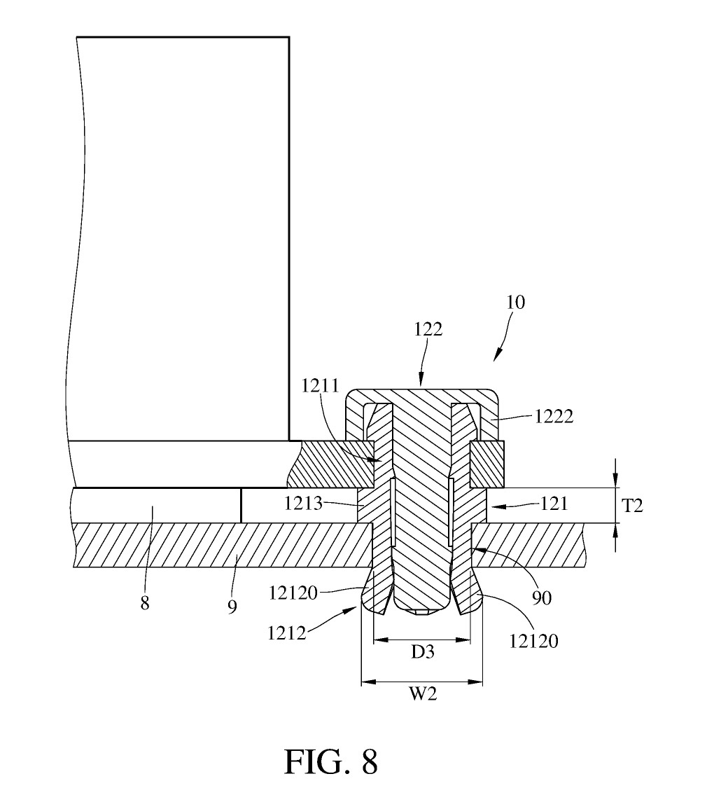

Please refer to FIG. 7 and FIG. 8. FIGS. 7-8 are side views of a process of assembling the assembly to the first object in FIG. 6. As shown in FIG. 7, the bolt 122 is firstly located at the first inserting position, and then the assembly 10 is disposed on the first object 9. Since the flexible arms 1211a of the second engaging portions 1212 of the hollow pillar 121 are not deformed and moved outward at this moment, the first outer diameter W1 of the second engaging portion 1212 is smaller than the inner diameter D3 of first through hole 90 of the first object 9, so that the second engaging portion 1212 is able to be inserted into the first through hole 90 of the first object 9.

Then, as shown in FIG. 8, the bolt 122 is moved to the second inserting position to force the flexible arms 1211a of the second engaging portions 1212 of the hollow pillar 121 to deform and move outward. At this moment, the second engaging portions 1212 press against the inner wall of the first through hole 90 of the first object 9, and the second outer diameter W2 of the second engaging portion 1212 is larger than the inner diameter D3 of the first through hole 90 of the first object 9. In addition, the bearing block 1213 is in contact with the first object 9, and the thickness T2 of the bearing block 1213 is the same as the thickness of the clamped member 8.

Because the second outer diameter W2 of the second engaging portion 1212 is larger than the inner diameter D3 of the first through hole 90 of the first object 9, the second object 11 is firmly fixed on the first object 9 without using any elastic member. Therefore, the second object 11 is prevented from moving with respect to the first object 9 so that the assembly 10 firmly fixed in place.

Furthermore, the bearing block 1213 can keep the second object 11 and the first object 9 to be spaced apart from each other so as to prevent the second object 11 and the first object 9 to press the clamped member 8 and prevent the second object 11 or the first object 9 from being deformed by the second engaging portion 1212. That is, the bearing block 1213 can be taken as a gasket, thus the there is no need to have additional gasket.

Then, the second object 11 and the hollow pillar 121 are two independent objects, so it is favorable to replace the second object 11 according to actual requirements. Furthermore, the hollow pillar 121 is able to be replaced if it is damaged due to friction, so it only needs to replace the damaged component, which is favorable for reducing the cost.

In addition, at this point, the head portion 1222 covers the first engaging portion 1211 of the hollow pillar 121, which makes the appearance simple.

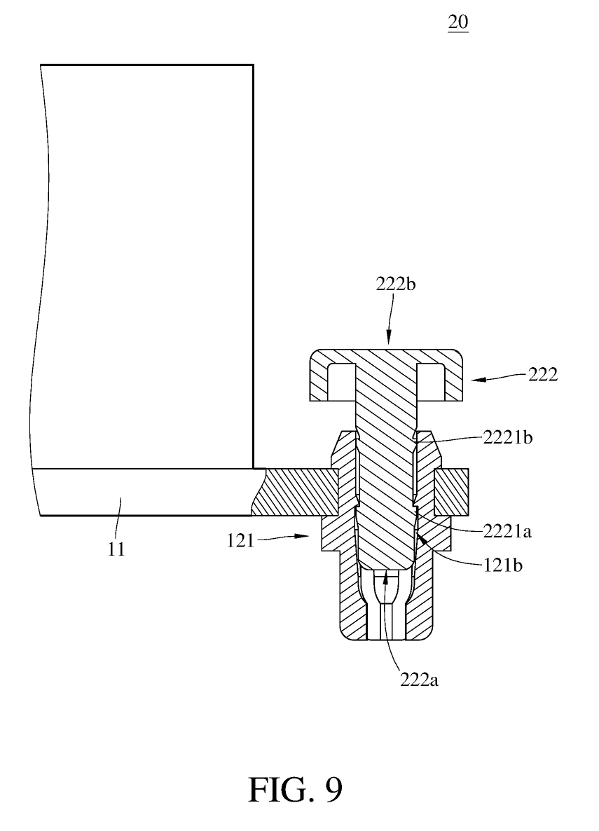

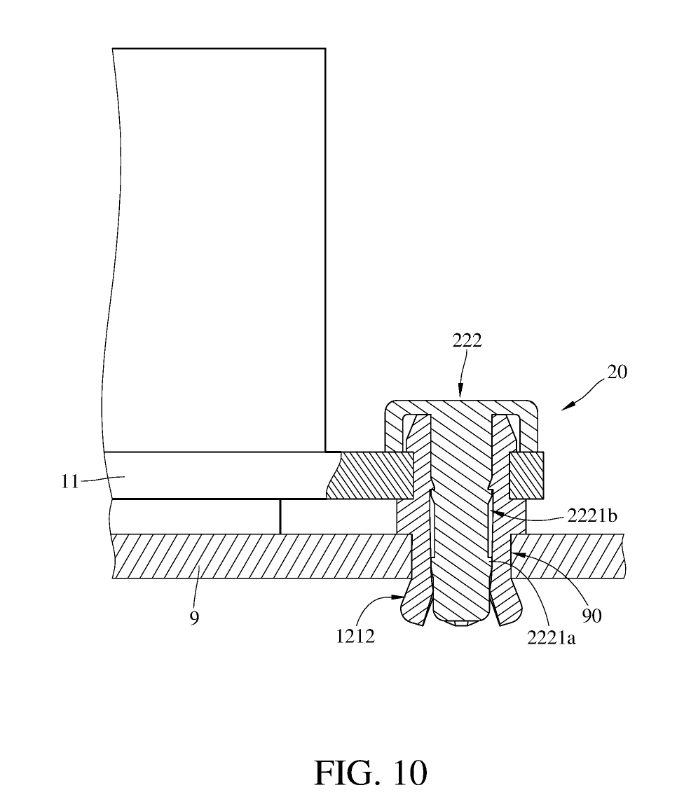

Please refer to FIG. 9 and FIG. 10. FIG. 9 is a side view of an assembly in accordance with another embodiment of the disclosure. FIG. 10 is a perspective view of the assembly in FIG. 9 being disposed on the first object. The assembly 20 in this embodiment is similar to the assembly 10 in FIG. 5. However, the bolt 222 of the assembly 20 is different from the bolt 122 of the assembly 10 in FIG. 5. The first positioning protrusion 2221a and the second positioning protrusion 2221b are located between the first end 222a and the second end 222b, and the former is closer to the first end 222a, the latter is closer to the second end 222b. As shown in FIG. 9, when the bolt 222 is at the first inserting position, the first positioning protrusion 2221a able to be located in the positioning recess 121b of the hollow pillar 121, and the second positioning protrusion 2221b is able to be removed from the positioning recess 121b.

As shown in FIG. 10, when the second engaging portion 1212 is inserted into the first through hole 90 of the first object 9, and the bolt 222 is moved to the second inserting position. At this moment, the first positioning protrusion 2221a is able to be removed from the positioning recess 121b, and the second engaging portion 1212 is expanded by the bolt 222. The bolt 222 is fixed in place at the second inserting position because the second positioning protrusion 2221b is located in the positioning recess 121b.

According to the latch and the assembly in above embodiments, the first object and the second object are respectively fixed to the first engaging portion and the second engaging portion of the hollow pillar, so the second object is immovable with respect to the first object, thereby the first object and the clamped member between the first object and the second object are prevented from being damaged by the second object. Moreover, the latch and the second object are assembled to be assembly through the first engaging portion. When the bolt is moved to the second inserting position, the second engaging portion is expanded by the bolt. In other words, the size of the second engaging portion becomes larger when the bolt is moved from the first inserting position to the second inserting position. Thus, the second engaging portion of the latch is able to be disposed on the first object easily when the bolt is at the first inserting position, and is able to be fixed to the first object when the bolt is at the second inserting position.

Furthermore, the bearing block can keep the second object and the first object to be spaced apart from each other so as to prevent the second object and the first object to press the clamped member and prevent the second object or the first object from being deformed by the second engaging portion. That is, the bearing block can be taken as a gasket, thus the there is no need to have additional gasket.

In addition, since the positioning protrusion is located in the positioning recess, the bolt is prevented from falling apart from the hollow pillar. Thus the bolt is able to be at the first inserting position or the second inserting position as expected.

Then, the second object and the hollow pillar are two independent objects, so it is favorable to replace the second object according to actual requirements. Furthermore, the hollow pillar is able to be replaced if it is damaged due to friction, so it only needs to replace the damaged component, which is favorable for reducing the cost.

1. A latch, adapted to fix a first object and a second object, and the latch comprising:
a hollow pillar, comprising a first engaging portion and a second engaging portion opposite to each other, the hollow pillar having an inserting hole passing through the first engaging portion and the second engaging portion, and the first engaging portion configured to be disposed on the second object; and
a bolt, inserted into the inserting hole and movable between a first inserting position and a second inserting position; when the bolt is moved from the first inserting position to the second inserting position along a direction from the first engaging portion pointing to the second engaging portion, and the second engaging portion is expanded by the bolt in order to be disposed on the first object;
wherein the first engaging portion comprises a plurality of engaging members spaced apart from one another, the plurality of engaging members surround a central axis of the inserting hole, and each of the plurality of engaging members has an engaging block at a side away from the inserting hole;
wherein the bolt has a head portion; when the bolt is at the second inserting position, the head portion surrounds and covers the plurality of engaging blocks.

2. (canceled)

3. The latch according to claim 1, wherein each of the plurality of engaging blocks has a guiding surface at the side away from the inserting hole.

4. The latch according to claim 1, wherein the second engaging portion comprises a plurality of flexible arms spaced apart from one another, the plurality of flexible arms surround the central axis of the inserting hole, and each of the plurality of flexible arms has a pushing block at a side close to the inserting hole.

5. The latch according to claim 4, wherein each of the plurality of pushing blocks has a guiding surface at the side close to the inserting hole.

6. The latch according to claim 1, wherein the hollow pillar further comprises a bearing block, and the first engaging portion and the second engaging portion are respectively located at two opposite sides of the bearing block.

7. The latch according to claim 1, wherein the bolt has a first positioning protrusion, the hollow pillar has a positioning recess at a side close to the inserting hole; when the bolt is at the first inserting position, the first positioning protrusion is located in the positioning recess; when the bolt is at the second inserting position, the first positioning protrusion is removed from the positioning recess.

8. The latch according to claim 7, wherein the bolt further comprises a second positioning protrusion; when the bolt is at the second inserting position, the second positioning protrusion is located in the positioning recess.

9. (canceled)

10. An assembly, adapted to be disposed on a first object, and the assembly comprising:
a second object, having a through hole; and
a latch, comprising:
a hollow pillar, comprising a first engaging portion and a second engaging portion opposite to each other, the hollow pillar having an inserting hole passing through the first engaging portion and the second engaging portion, and the first engaging portion disposed through the through hole of the second object; and
a bolt, disposed through the through hole of the second object, inserted into the inserting hole and movable between a first inserting position and a second inserting position; when the bolt is moved from the first inserting position to the second inserting position along a direction from the first engaging portion pointing to the second engaging portion, the second engaging portion is expanded by the bolt in order to be disposed on the first object;
wherein the first engaging portion comprises a plurality of engaging members spaced apart from one another, the plurality of engaging members surround a central axis of the inserting hole, and each of the plurality of engaging members has an engaging block at a side away from the inserting hole, and the engaging blocks are fastened to the second object;
wherein the bolt has a head portion; when the bolt is at the second inserting position, the head portion surrounds and covers the plurality of engaging blocks.

11. (canceled)

12. The assembly according to claim 10, wherein each of the plurality of engaging blocks has a guiding surface at the side away from the inserting hole.

13. The assembly according to claim 10, wherein the second engaging portion comprises a plurality of flexible arms spaced apart from one another, the plurality of flexible arms surround the central axis of the inserting hole, and each of the plurality of flexible arms has a pushing block at a side close to the inserting hole.

14. The assembly according to claim 13, wherein each of the plurality of pushing blocks has a guiding surface at the side close to the inserting hole.

15. The assembly according to claim 10, wherein the hollow pillar further comprises a bearing block, the first engaging portion and the second engaging portion are respectively located at two opposite sides of the bearing block, and the second object and the first engaging portion are at the same side of the bearing block.

16. The assembly according to claim 10, wherein the bolt has a first positioning protrusion, the hollow pillar has a positioning recess at a side close to the inserting hole; when the bolt is at the first inserting position, the first positioning protrusion is located in the positioning recess; when the bolt is at the second inserting position, the first positioning protrusion is removed from the positioning recess.

17. The assembly according to claim 16, wherein the bolt further comprises a second positioning protrusion; when the bolt is at the second inserting position, the second positioning protrusion is located in the positioning recess.

18. (canceled)
